(19) United States
(12) Patent Application Publication
(10) Pub. No.: US 2020/0023442 A1
(43) Pub. Date: Jan. 23, 2020

(54) METHOD FOR COATING SOLID DIAMOND MATERIALS

(71) Applicant: GUEHRING KG, Albstadt (DE)

(72) Inventors: Faik DOGAN, Winterlingen (DE); Andreas SAGR, Albstadt (DE); Tobias FECHNER, Albstadt (DE); Dominik SPOHN, Balingen (DE); lmmo GARRN, Ertingen (DE)

(73) Assignee: GUEHRING KG, Albstadt (DE)

(21) Appl. No.: 16/523,571

(22) Filed: Jul. 26, 2019

Related U.S. Application Data
(63) Continuation of application No. PCT/EP2018/052283, filed on Jan. 30, 2018.

(30) Foreign Application Priority Data
Jan. 31, 2017 (DE) 102017201487.3

(51) Int. Cl. B23B 27/14; B23C 9/00; B23K 1/19; C23C 14/18; C23C 14/58; C23C 14/06

(52) U.S. Cl. CPC B23B 27/148; B23C 9/005; B23K 1/19; B23B 2226/315; C23C 14/5806; C23C 14/0676; C23C 14/18

(57) ABSTRACT

A method for coating solid diamond materials, to solder or bond coated diamond materials into a metallic surface or a second diamond surface under ambient air. The diamond materials are at least partially coated under a noble gas atmosphere by a vapour depositing process, the coating is performed with at least one carbide-forming chemical element selected from among B, Ti, Zr, Hf, V, Nb, Ta, Cr, Mo and W; some diamond carbon is converted into elemental carbides, which form an elemental carbide layer; and wherein there is a stoichiometric excess of the chemical element in relation to the elemental carbides formed, so an element layer is deposited onto the surface of the elemental carbide layer or a mixed elemental carbide/element layer forms and is deposited on the element layer or mixed elemental carbide/element layer. Also, a machine component, in particular a tool, with a soldered-in solid PCD.

The present invention relates to a method for coating solid diamond materials according to the preamble of claim 1. The invention further relates to a method for producing a machine component having a functional region made of a coated solid PCD according to the preamble of claim 17 and a machine component according to claim 19.

The term “machine component” is also understood in the context of the present invention in particular as a cutting tool or a tool for machining which can be present in all embodiments well known to the person skilled in the art.

Tools, in particular those for machining, comprising a tool head, a tool shank and having a clamping portion for receiving in a tool holder are known in a wide variety of forms from the prior art.

Such tools have functional region topologies in their cutting region which are adapted to the specific requirements of the materials to be machined.

The said tools comprise those which are configured, for example, as drilling, milling, countersinking, turning, tapping, contouring or reaming tools. These can have cutting bodies and/or guide strips as functional region, wherein the functional bodies are soldered onto a support or can be configured, for example, as an exchangeable or replaceable cutting plate. Furthermore, it is usually also possible to solder onto a replaceable cutting plate support.

Typically such tool heads have functional regions which impart to the tool a high wear resistance during the machining of highly abrasive materials such as Al—Si alloys or stone. The wear resistance is increased if, for example, as in DE 20 2005 021 817 U1 of the present applicant, tool heads are provided with a functional layer which comprise a super hard material such as cubic boron nitride (CBN) or polycrystalline diamond (PCD).

In order to produce a tool having long lifetimes with regard to mechanical or thermal requirements for drilling, milling or reaming, in the prior art for example methods have been described for applying a polycrystalline film in particular a film of diamond material to non-diamond substrates. For example, U.S. Pat. No. 5,082,359 describes the application of a polycrystalline diamond film by means of chemical vapour deposition (CVD).

Furthermore, further improved diamond-coated hard metal or cermet tools are described in DE 10 2015 208 742 A1 of the applicant.

Furthermore, the manufacture of so-called solid PCDs is known in which shaped bodies of polycrystalline diamonds and sintering adjuvants are sintered to form polycrystalline diamond bodies, so-called solid PCDs.

Such solid PCDs are available commercially and can, for example, be soldered onto a hard metal substrate using specific solders in an active soldering process in protective gas or vacuum.

In this case, it has proved particularly problematical that one the one hand a poor wetting of the solid PCDs by the metallic solder alloy used and on the other hand a tendency to conversion of the diamond lattice into a graphite lattice are obtained.

The relationships and the problems of soldering diamond bodies onto hard metal substrates, the corresponding interface reactions and the wetting problems are described in Tillmann et al. Mat.-Wiss. u. Werkstofftech. 2005, 36, No. 8, 370-376. Although synthetic diamonds now play a major role as a result of their exceptional properties in the materials technology field, the joining of diamond together with other materials is found to be problematical however since diamonds do not have a metallic structure but have a cubic lattice in which the C—C bonds are covalent sp³ bonds. Regardless of the fact that Ti-containing active solder alloys are able to wet diamonds, according to Tillmann et al., the interface reactions need to be further researched. It is assumed that a carbide reaction layer is formed at the interface between diamond crystal surface and solder but analyses of real diamond hard metal solder joins have shown that the presence of hard metal can negatively influence the Ti migration to the diamond surface.

Depending on the solder process parameters, in some cases in Tillmann et al. there was no significant Ti enrichment at the solder/diamond interface. Higher solder temperatures and longer holding times can however bring about a significant intensification of the diamond-side interface reactions so that a, for example, Ti-containing reaction layer can be clearly distinguished. Furthermore, there is an additional risk of oxidation as a result and there is a tendency to graphite formation, which overall drives up the costs due to the production rejects caused by the effects described.

According to Tillmann et al., Ni-base solders—in the same way as Ti-containing solder alloys—show a good wetting in joining reactions with the diamond surface. Less active elements such as Cr, Si or B also cause interface reactions. The results of the investigation show a clear dependence between wetting and contents of Cr, Si or B. However, according to Tillmann et al., it must be taken into account that higher contents of interface-active elements result in more intensive decomposition reactions which can result in some preliminary damage to the diamond. According to Tillmann et al., vacuum soldering is one of the most promising joining methods for producing diamond tools although the fact must be borne in mind that at elevated temperatures in air above about 500 ° C. and in vacuum above about 1300° C., diamonds begin to decompose which is why it is crucial to provide a joining method in which these critical temperatures are not exceeded.

According to Tillmann et al. the covalent bonds of diamond with their bound electrons are the greatest obstacle for a metallurgical interaction between solder alloy and diamond. The prior art of Tillmann et al. proposes to overcome this obstacle by using a solder alloy which contains active elements which directly react chemically with the diamond. In particular, Tillmann et al. suggests using titanium or other “refractory metals” not designated in detail for this purpose.

In particular, Tillmann et al. describe a carbide reaction which results in the formation of a TiC reaction layer which serves as key for a wetting reaction since carbide reaction products also have metallic bonds in the sense of an electron gas. In contrast to the active soldering of oxide or non-oxide ceramics, for thermodynamic reasons diamonds do not necessarily require such reactive active metals in order to promote an interface reaction. Tillmann et al. experiment with a copper base solder and a synthetic diamond in which a thin reaction layer was detected, which indicates that the surface of the diamond was partially decomposed with the formation of carbides from Cr and Si.

Tillmann et al. point out however that in the literature at the time (2005) there is still no completely clear picture of what actually takes place at the solder-diamond interface.

U.S. Pat. No. 5,626,909 A further discloses tool sets of polycrystalline diamond which after coating with a bonding layer and a protective layer in air can be soldered onto a support. The bonding layer is produced by applying (by means of CVD or PVD) a metal layer of, for example, tungsten or titanium and heat treating to produce a corresponding metal carbide at the interface to the tool insert, i.e. to the diamond. The protective layer applied in a further step consists of a metal such as silver, copper, gold, palladium, platinum, nickel and alloys thereof and alloys of nickel with chromium.

Furthermore, US 2007/0 160 830 A1 describes the coating of grinding particles of diamond, for example, wherein two layers are applied successively. An inner layer of a metal carbide, nitride or carbonitride (preferably TiC) and an outer layer of tungsten. The coated grinding particles can be further processed in air by simple soldering.

Starting from the prior art of U.S. Pat. No. 5,626,909 A it is therefore the object of the present invention to provide a method by means of which diamond materials can be produced which can be soldered or bonded into a metallic surface or against another diamond surface safely and reliably in ambient air.

This object is solved by a method for coating solid diamond materials according to claim 1 and by a method for producing a machine component according to claim 17.

A coated solid PCD according to claim 15 and a machine component according to claim 18 also solve the object.

In particular, the present invention describes a method for coating solid diamond materials in order to solder or bond the coated diamond materials into a metallic surface or a second diamond surface under ambient air; wherein

the diamond materials are at least partially coated in a noble gas atmosphere by means of a vapour deposition process, wherein the coating is accomplished using at least one carbide-forming chemical element which is selected from the group consisting of: B, Ti, Zr, Hf, V, Nb, Ta, Cr, Mo, W; wherein
a partial quantity of the diamond carbon of the diamonds contained in the surface of the diamond materials is converted into elemental carbides which form an elemental carbide layer; wherein
the chemical element is present in stoichiometric excess in the molar ratio to the elemental carbides formed so that an element layer is deposited on the surface of the elemental carbide layer or a mixed elemental carbide/element layer is formed,
wherein
a transition layer is deposited on the resulting element layer or mixed elemental carbide/element layer; and that
the transition layer comprises at least one layer which is selected from the group consisting of: boride layers, nitride layers, oxide layers as well as mixed layers thereof, carbonitride layers, oxynitride layers and/or carboxynitride layers.

As a result of the coating of the diamond surface with a carbide-forming element a part of the diamond carbide migrates into the corresponding elemental carbide. This elemental carbide layer is firmly bonded to the PCD layer. By using the carbide-forming element or elements in stoichiometric excess, an element layer containing the coating element (or elements) is formed on the elemental carbide layer.

Both layers—the elemental carbide layer on the one hand, the element layer on the other hand—have metallic binding properties which results in a strong adhesion of the element layer on the carbide layer. Furthermore, as a result of its metallic properties, the element layer or the elemental carbide layer/element mixed layer can already be well wetted with a metallic solder so that stable solder connections to the substrate can be formed.

However, an even better wettability and ultimately adhesion of the solder on the surface of the component to be soldered is obtained by application of a transition layer which comprises at least one layer which is selected from the group consisting of: boride layers, nitride layers, oxide layers as well as mixed layers thereof, carbonitride layers, oxynitride layers and/or carboxynitride layers. By means of these measures robust tool parts are obtained, wherein the solder connection between, e.g. solid PCD and substrate surface has significantly improved lifetimes.

It is preferred within the scope of the present invention that solid diamond materials of monocrystalline diamonds or polycrystalline diamonds are used.

The present invention has a particular importance when sintered-together diamond particles of polycrystalline diamonds, so-called “solid PCDs” are used as solid diamond materials.

It is advantageous if solid PCDs are used which contain sintering adjuvants which are selected from the group consisting of: Al, Mg, Fe, Co, Ni as well as mixtures thereof. These metals can also contribute to the formation of a solder-wettable carbide-containing diamond/solder interface.

Prefabricated untreated solid PCDs can be used which have a substructure of hard metal.

However, it can also be appropriate and advantageous within the framework of the invention to remove at least largely from the solid PCDs the manufacturing-dependent sintering adjuvants and/or the hard metal substructure in order to obtain a better controllable elemental carbide/element mixed layer.

Typically the sintered diamond particles have a mean grain size of 0.5 μm to 100 μm.

It is a preferred embodiment of the present invention to deposit a transition layer on the resulting element layer or elemental carbide/element mixed layer.

Such a transition layer can be of the element type (B, C, N, O) and can be deposited on the resulting element layer or element carbide/element mixed layer, wherein boride layers, nitride layers, oxide layers and mixed layers thereof, in particular carbonitride layers, an oxynitride layers and/or carboxynitride layers are included.

In practice, it has been found that a layer which satisfies the following general formula is preferred as transition layer:

(E1, E2, E3 . . . Exy)x(BCNO)_{y}

wherein E is an element which is selected from the group consisting of: Mg, B, Al, Si, Ti, Zr, Hf, V, Nb, Ta, Cr, Mo, W; wherein x lies in the range of 0-2 and y lies in the range of 0.5-2, wherein preferably a range of 0.5 to 1.1 is preferred for x and y, in each case independently of one another.

Such transition layers can protect the solid PCDs from thermal and chemical influences during the soldering process.

In order to produce or to deposit the elemental carbide layer, in practice a physical vapour deposition (PVD) process has proved successful, wherein preferably an argon atmosphere is used as noble gas atmosphere.

Typically the PVD process is carried out in a temperature range from 400° C. to 600° C., in particular 450° C. at a bias voltage of 0 to minus 1000 V and a pressure of 100 mPa to 10 000 mPa for a duration of 1 min to 20 min, in particular 5 min.

Preferably after coating, a tempering step is carried out at 200° C. to 600° C. for a time between 1 min and 60 min.

The transition layer can preferably also be applied to the elemental carbide layer by means of PVD in a temperature range from 400° C. to 600° C., in particular 450° C. at a bias voltage of 0 to minus 1000 V and a pressure of 100 mPa to 10 000 mPa for a duration of 0.1 h to 3 h.

For soldering in solid PCDs coated by means of the method according to the invention, the transition layer can be wetted with a solder, optionally using fluxes, in an air atmosphere and the solid PCDs thus formed can easily be soldered into a machine component, in particular a tool.

A coated solid PCD can be obtained as a result of the present invention.

Also several solid PCDs can be soldered together to obtain a larger solid PCD.

Thus, by means of the method according to the invention, it is possible to produce a machine component with at least one functional region made of a coated solid PCD as well as a metallic support body, wherein

the solid PCD is fixed on at least one surface of the metallic support body by means of a solder connection, wherein for example, a hard solder based on silver or nickel or another suitable hard solder well known to the person skilled in the art is used as solder; and
the solder connection between coated solid PCD and support body is produced at a maximum of 700° C. in an air atmosphere under normal pressure.

Thus, for the first time practical machine components with soldered-in solid PCDs are available within the scope of the invention, which enable crack-free solder connections and long lifetimes.

Such machine components can be tools, in particular machining tools or asphalt or stone milling heads or drilling heads.

Further advantages and features of the invention are obtained from the description of exemplary embodiments.

### EXAMPLE

In the present example, by coating a commercially available solid PCD body it should be possible to solder in the solid PCD body—without a protective gas atmosphere—and therefore in an air atmosphere with the aid of a bonding layer. To this end, a surface which is readily wettable by the solder used and which also binds firmly to the diamond should be created so that the PCD-bonding layer interface does not become the weak point of the join and the tool thus produced meets all the loads and requirements on the tool and high lifetimes are achieved.

For the present exemplary embodiment four different commercially available PC D types were used.

A square plate was selected as the test sample geometry. The types of solid PCD used comprise polycrystalline diamond material which contains cobalt along with other metals.

The solid PCD test samples were tempered with several carbide-forming metals or elements, in the case of the example, titanium and zirconium and treated at a temperature of about 600° C. and a voltage bias of about −150 V in a PVD coating system. The formation of metal carbides, in the present case, TiC and ZrC was shown by means of X-ray diffractometry.

The thickness of the carbide layer was about 0.01 μm measured by means of X-ray diffractometry and scanning electron microscopy.

Following the formation of the carbide layer, a boride transition layer was deposited on the elemental carbide layer by vapour deposition of elemental boron in the presence of oxygen and nitrogen by means of PVD. The conditions for the application of the transition layer were a temperature gradient of 400° C. to 600° C. which was passed through at a rate of 10° C./min and then held at 500° C. The PVD process was carried out at a bias voltage of about minus 600 V and a pressure of about 2000 mPa for a duration of 2 h.

Such coated solid PCDs were then soldered onto a hard metal plate by means of a solder alloy, in the case of the example, of Ag—Cu—Zn—Mn—Ni in an ambient air atmosphere at about 700° C. and a shear test was carried out. Following the shear test a further scanning electron microscope investigation was carried out in order to assess whether cracks or ruptures occurred in the solder or in the interface and/or whether there was any damage to the diamond surface.

Here it was surprisingly found that in the course of the usual shear stress tests, no ruptures or cracks appeared in the solder layer nor in the interface to the solid PCD.

The diamond surface itself was also free from damage.

1. A method for coating solid diamond materials in order to solder or bond the coated diamond materials into a metallic surface or a second diamond surface under ambient air; wherein
the diamond materials are at least partially coated in a noble gas atmosphere by means of a vapour deposition process, wherein the coating is accomplished using at least one carbide-forming chemical element which is selected from the group consisting of: B, Ti, Zr, Hf, V, Nb, Ta, Cr, Mo, W; wherein
a partial quantity of the diamond carbon of the diamonds contained in the surface of the diamond materials is converted into elemental carbides which form an elemental carbide layer; wherein
the chemical element is present in stoichiometric excess in the molar ratio to the elemental carbides formed so that an element layer is deposited on the surface of the elemental carbide layer or a mixed elemental carbide/element layer is formed,
wherein:
a transition layer is deposited on the resulting element layer or mixed elemental carbide/element layer; and
the transition layer comprises at least one layer which is selected from the group consisting of: boride layers, nitride layers, oxide layers as well as mixed layers thereof, carbonitride layers, oxynitride layers and/or carboxynitride layers.

2. The method according to claim 1, wherein the solid diamond materials comprise solid diamond materials of monocrystalline diamonds or polycrystalline diamonds.

3. The method according to claim 1, wherein the solid diamond materials comprise sintered-together diamond particles of polycrystalline diamonds (solid PCDs).

4. The method according to claim 3, wherein the solid PCDs contain sintering adjuvants which are selected from the group consisting of: Al, Mg, Fe, Co, Ni as well as mixtures thereof.

5. The method according to claim 3, wherein the solid diamond materials comprise solid PCDs which have a substructure of hard metal.

6. The method according to claim 5, wherein sintering adjuvants and/or the hard metal substructure are at least largely removed from the solid PCDs.

7. The method according to claim 3, wherein the sintered-together diamond particles have a mean grain size of 0.5 μm to 100 μm.

8. The method according to claim 1, wherein a layer which satisfies the following general formula is used as transition layer:
(E1, E2, E3 . . . Exy)x(BCNO)_{y}
wherein E is an element which is selected from the group consisting of: Mg, B, Al, Si, Ti, Zr, Hf, V, Nb, Ta, Cr, Mo, W; wherein x lies in the range of 0-2 and y lies in the range of 0.5-2, and B is boron, C is carbon, N is nitrogen and O is oxygen.

9. The method according to claim 8, wherein x and y lie in the range from 0.5 to 1.1.

10. The method according to claim 1, wherein the vapour deposition process is a physical vapour deposition (PVD) process.

11. The method according to claim 1, wherein the vapour deposition process is carried out in a temperature range from 400° C. to 600° C. at a bias voltage of 0 to minus 1000 V and a pressure of 100 mPa to 10 000 mPa for a duration of 1 min to 20 min.

12. The method according to claim 1, wherein the method further comprises carrying out, after coating, a tempering step at 200° C. to 600° C. for a time between 1 min and 60 min.

13. The method according to claim 1, wherein the transition layer is also applied to the elemental carbide layer by means of PVD in a temperature range from 400° C. to 600° C., at a bias voltage of 0 to minus 1000 V and a pressure of 100 mPa to 10 000 mPa for a duration of 0.1 h to 3 h.

14. The method according to claim 1, wherein the transition layer is wetted with a solder, in an air atmosphere.

15. A coated solid PCD obtained by a method according to claim 1.

16. The solid PCD according to claim 15, wherein several solid PCDs are soldered together.

17. A method for producing a machine component with at least one functional region made of a coated solid PCD according to claim 15 as well as a metallic support body,
wherein:
the solid PCD is fixed on at least one surface of the metallic support body by a solder connection, wherein a hard solder is used as solder; and
the solder connection between the coated solid PCD and the support body is produced at a maximum of 700° C. in an air atmosphere under normal pressure.

18. A machine component obtained by a method according to claim 17.

19. The machine component according to claim 18, wherein the machine component is a cutting tool.

20. The method according to claim 10, wherein an argon atmosphere is used as a noble gas atmosphere in the PVD process.

21. The method according to claim 14, wherein the transition layer is wetted with solder and fluxes in an air atmosphere.

22. The machine component according to claim 18, wherein the machine component is a machining tool or an asphalt or a stone milling head or a drilling head.
